(19) United States
(12) Patent Application Publication
(10) Pub. No.: US 2026/0271677 A1
(43) Pub. Date: Sep. 10, 2026

(54) REUSABLE FLEXIBLE PROBE WITH FERROMAGNETIC ALIGNMENT FOR CHIP TESTING

(71) Applicant: International Business Machines Corporation, Armonk, NY (US)

(72) Inventors: Uzma Rana, Slingerlands, NY (US); Reinaldo Vega, Mahopac, NY (US); Takashi Ando, Eastchester, NY (US); David Wolpert, Poughkeepsie, NY (US)

(21) Appl. No.: 19/073,438

(22) Filed: Mar. 7, 2025

(51) Int. Cl. H10P 74/00; H10W 46/00

(52) U.S. Cl. CPC H10P 74/27; H10W 46/00; H10W 46/301

(57) ABSTRACT

According to an embodiment of the present invention, a semiconductor device includes a flexible layer substrate. A plurality of ferromagnetic fill regions extend through the flexible layer substrate. A product chip is located under the flexible layer substrate. A plurality of ferromagnetic alignment marks extend through a portion of the product chip. The plurality of ferromagnetic fill regions and the plurality of ferromagnetic alignment marks are aligned through ferromagnetism.

### FIELD OF INVENTION

The present disclosure relates to semiconductor testing devices, and more particularly to a reusable flexible probe with ferromagnetic alignment features for testing chip-level interconnects.

### BACKGROUND

Semiconductor device testing is an essential part of the manufacturing process to ensure product quality and reliability. As semiconductor devices continue to shrink in size and increase in complexity, testing methodologies must evolve to keep pace with these advancements. One area of particular interest is the testing of chip-level interconnects, which are responsible for transmitting signals and power between different components of a semiconductor device.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an embodiment of the present invention, a semiconductor device includes a flexible layer substrate. A plurality of ferromagnetic fill regions extend through the flexible layer substrate. A product chip is located under the flexible layer substrate. A plurality of ferromagnetic alignment marks extend through a portion of the product chip. The plurality of ferromagnetic fill regions and the plurality of ferromagnetic alignment marks are aligned through ferromagnetism.

According to an embodiment of the present invention, a semiconductor device includes a flexible layer substrate. A plurality of ferromagnetic fill regions extend through the flexible layer substrate. A product chip is located under the flexible layer substrate. A stop layer formed directly atop the product chip. A plurality of ferromagnetic alignment marks extend through the stop layer and a portion of the product chip. The plurality of ferromagnetic fill regions and the plurality of ferromagnetic alignment marks are aligned through ferromagnetism.

According to an embodiment of the present invention, a semiconductor device includes a flexible layer substrate. A plurality of flexible layer interconnects extend through the flexible layer substrate. A plurality of ferromagnetic fill regions extend through the flexible layer substrate. A product chip is located under the flexible layer substrate. A stop layer is connected to the frontside of the product chip. A plurality of product chip interconnects extend through the stop layer and the product chip. A plurality of ferromagnetic alignment marks extend through the stop layer and a portion of the product chip. The plurality of ferromagnetic fill regions and the plurality of ferromagnetic alignment marks are aligned through ferromagnetism.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates a cross-sectional view of a layered semiconductor structure, according to the embodiment of the present invention.

FIG. 2 illustrates a cross-sectional view of a flexible layer with interconnect formation, according to the embodiment of the present invention.

FIG. 3 illustrates a cross-sectional view of a flexible layer with interconnects and a ferromagnetic (FM) fill, according to the embodiment of the present invention.

FIG. 4 illustrates a cross-sectional view of delamination of the reusable layer from the carrier wafer, according to the embodiment of the present invention.

FIG. 5 illustrates a cross-sectional view of a product wafer ready for testing, according to the embodiment of the present invention.

FIG. 6 illustrates a cross-sectional view of a product wafer after formation of a third plurality of trenches, according to the embodiment of the present invention.

FIG. 7 illustrates a cross-sectional view of a product wafer after FM fill deposition, according to the embodiment of the present invention.

FIG. 8 illustrates a cross-sectional view of a reusable layer and a product wafer after optical alignment, according to the embodiment of the present invention.

FIG. 9 illustrates a cross-sectional view of a reusable layer and a product wafer after FM fine alignment, according to the embodiment of the present invention.

FIG. 10 illustrates a cross-sectional view of a reusable layer and a product wafer with a probe testing configuration, according to the embodiment of the present invention.

FIG. 11 illustrates a cross-sectional view of separation of the reusable layer from the product wafer, according to the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Traditional probe cards used for chip-level testing often face challenges when dealing with high-density interconnects and fine pitch structures. These probes may struggle to maintain consistent contact with test pads, potentially leading to inaccurate test results or damage to the device under test. Additionally, as the number of test points increases, the force required to establish proper electrical contact can become substantial, potentially causing warpage or other structural issues in the wafer or chip being tested. Therefore, these existing probes make it infeasible to package the post-probe chip with the top metal layer intact.

Reusability is also a factor in probe design, as frequent replacement of probe components can lead to increased costs and downtime in the testing process. Probes that can withstand multiple test cycles without degradation in performance are desirable for maintaining efficient and cost-effective testing operations.

As the semiconductor industry continues to advance, there is an ongoing need for improved testing solutions that can address these challenges. Innovations in probe design, materials, and alignment techniques have the potential to enhance the accuracy, efficiency, and reliability of chip-level interconnect testing.

By incorporating ferromagnetic alignment features in a probing structure, precision in positioning the chip under testing is enabled. This alignment capability is particularly beneficial in testing chips with fine-pitch interconnects or complex layouts.

Additionally, implementing a removable and reusable flexible layer allows for multiple testing cycles without the need for replacement of the probing structure, potentially reducing costs and improving efficiency in semiconductor manufacturing and quality control processes. The reusable nature of the probe structure also offers benefits in terms of sustainability and resource efficiency in semiconductor testing processes. By allowing multiple uses, the probe structure reduces material waste and potentially lower the overall environmental impact of chip testing procedures.

The flexibility of the probe structure provide advantages in accommodating variations in chip topography or surface irregularities. This characteristic enables more consistent and reliable electrical connections during testing, potentially leading to more accurate test results.

The present invention is directed to a reusable flexible probe structure for testing semiconductor chips. This probe structure incorporates ferromagnetic alignment features to facilitate precise positioning during testing procedures. The probe structure is not only bump-free but also enables dies to be tested before integration into 2.5D/3D packaging. The flexible nature of the probe structure allows for improved contact with chip surfaces, potentially enhancing the reliability and accuracy of testing processes.

The probing structure is formed through multistage processing, where the first stage deposits a polymer layer on a carrier wafer. The second stage forms interconnects in the flexible layer. The third stage performs a ferromagnetic (FM) fill in the flexible layer. The third stage performs a delamination of the polymer layer from the carrier wafer. The fourth stage forms FM alignment marks on a product chip. The fifth stage performs optical alignment of the flexible layer directly atop the product chip. The sixth stage performs FM fine alignment of the flexible layer with the product chip.

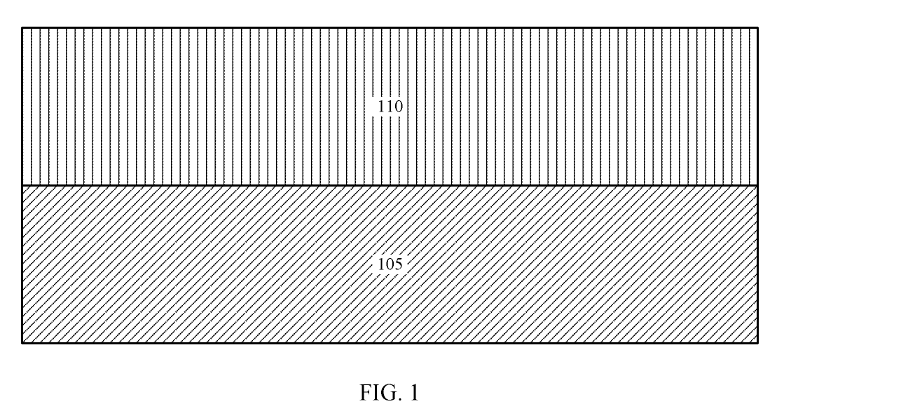

FIG. 1 illustrates a cross-sectional view of a layered semiconductor structure, according to the embodiment of the present invention. The structure comprises a carrier wafer 105 shown in the lower portion of the figure. A flexible layer 110 is positioned directly atop of the carrier wafer 105. The flexible layer 110 extends across the entire width of the carrier wafer 105, forming a uniform upper layer in the structure. Additionally, the flexible layer 110 comprises a flexible polymer material (e.g., PEDOT:PSS) which can be used on a bumped or bumpless dies or chiplet.

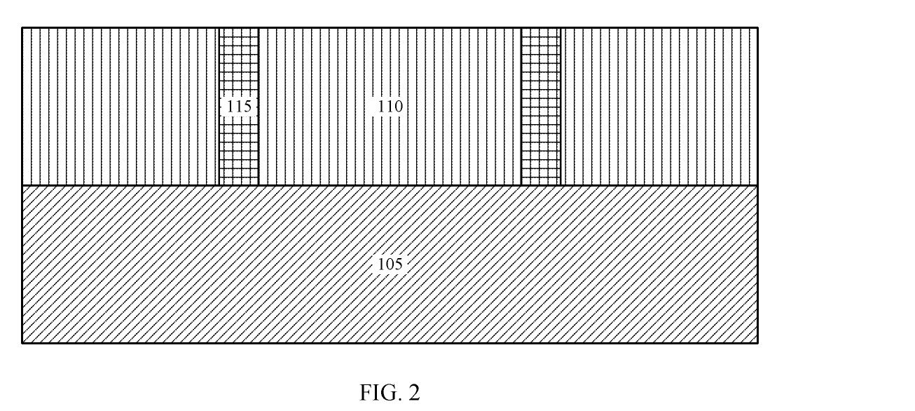

FIG. 2 illustrates a cross-sectional view of the flexible layer 110 with interconnect 115 formation, according to the embodiment of the present invention. The structure includes the carrier wafer 105 as the base layer. Above the carrier wafer 105 is the flexible layer 110. The flexible layer 110 includes flexible layer interconnects 115, which are integrated within the flexible layer 110. The flexible layer interconnects 115 are positioned at specific intervals along the flexible layer 110, creating a structured arrangement for electrical connectivity. The flexible layer interconnects 115 are formed through deposition of an industry standard metal, such as copper (Cu) or tungsten (W).

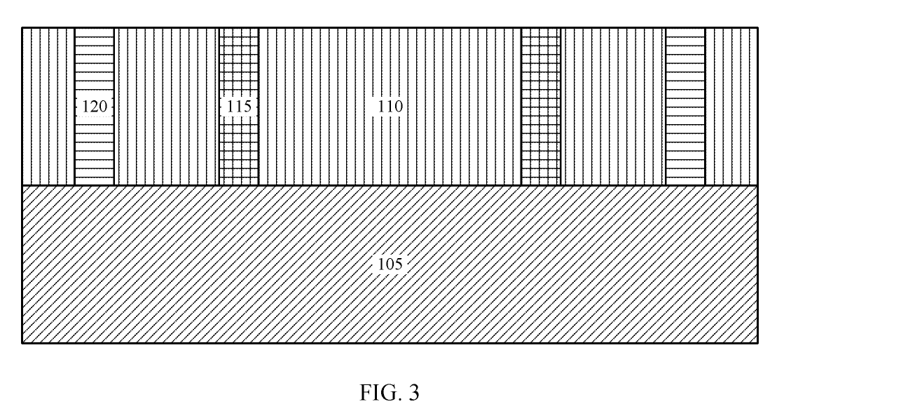

FIG. 3 illustrates a cross-sectional view of the flexible layer 110 with interconnects 115 and FM fill 120 regions, according to the embodiment of the present invention. After flexible layer interconnects 115 are formed, a first plurality of trenches (not shown) are formed through the flexible layer 110 to expose a frontside surface of the carrier wafer 105. The first plurality of trenches between the flexible layer interconnects 115 and an edge of the flexible layer 110. An FM fill material is then deposited in the first plurality of trenches to form FM fill region 120. FM fill region 120 may be comprised of any ferromagnetic material, such as cobalt (Co) or nickel (Ni). Hereinafter, the combination of the flexible layer 110 with formed flexible layer interconnects 115 and FM fill region 120 is referred to as the reusable layer.

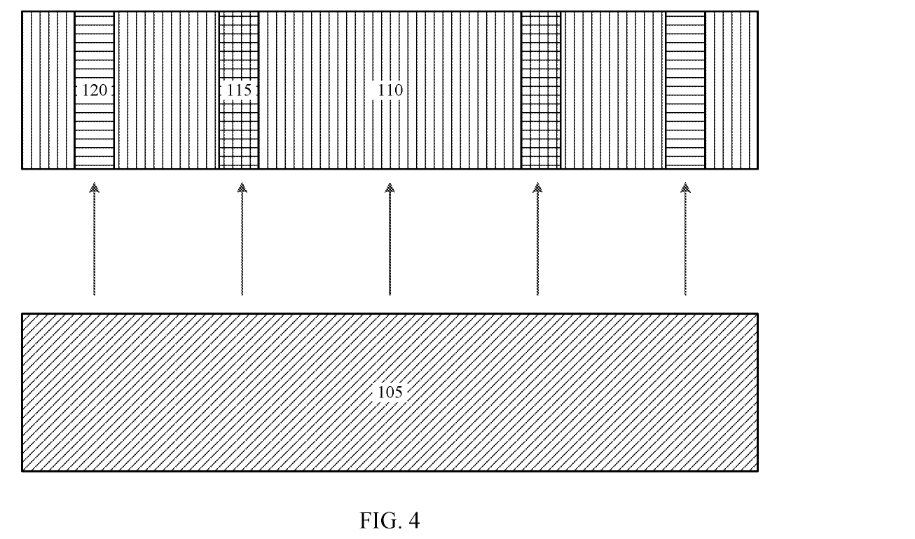

FIG. 4 illustrates a cross-sectional view of delamination of the reusable layer 110, 115, 120 from the carrier wafer 105, according to the embodiment of the present invention. Once the reusable layer 110, 115, 120 is fully formed as the flexible layer 110 with flexible layer interconnects 115 and FM fill region 120, the reusable layer 110, 115, 120 is delaminated from the carrier wafer 105. Delamination comprises removal of the reusable layer 110, 115, 120 from the carrier wafer 105 for placement, alignment, and testing with a product wafer.

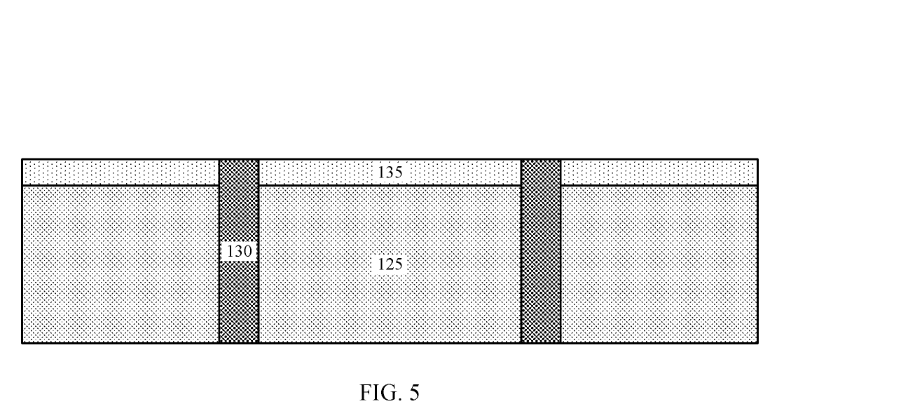

FIG. 5 illustrates a cross-sectional view of a product wafer ready for testing, according to the embodiment of the present invention. Product chip 125 has an etch/CMP stop layer 135 formed on a frontside surface of the product chip 125, such as through CMP. A second plurality of trenches (not shown) are formed through the etch/CMP stop layer 135 and the product chip 125. Spacing of the second plurality of trenches matches the spacing of the flexible layer interconnects 115. The product chip interconnects 130 are formed within the second plurality of trenches through deposition of an industry standard metal, such as copper (Cu) or tungsten (W).

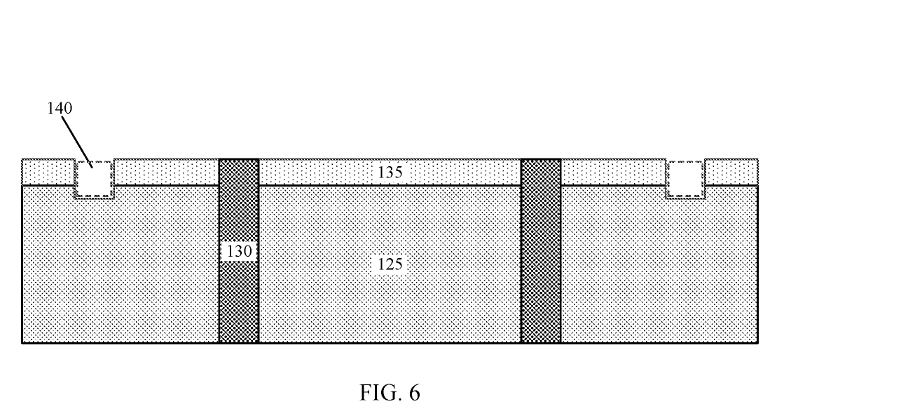

FIG. 6 illustrates a cross-sectional view of a product wafer after formation of a third plurality of trenches 140, according to the embodiment of the present invention. A third plurality of trenches 140 is formed through the stop layer 135 and a portion of the product chip 125. Each trench in the third plurality of trenches 140 is formed between an edge of the product chip 125 and a product chip interconnect 130.

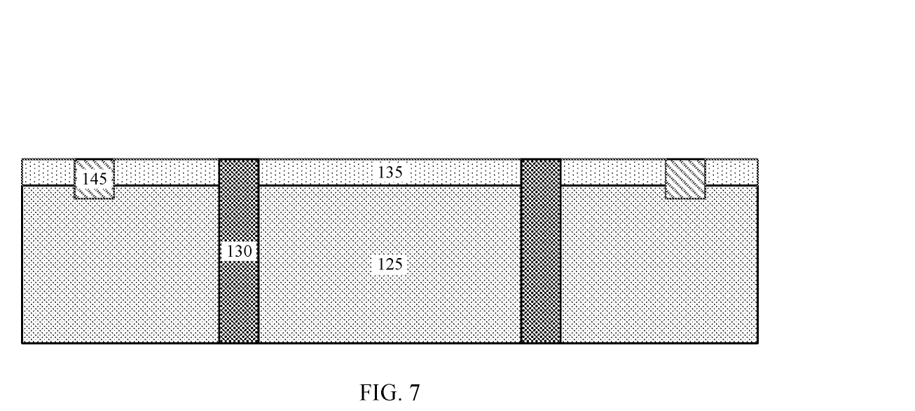

FIG. 7 illustrates a cross-sectional view of a product wafer after FM fill deposition, according to the embodiment of the present invention. An FM metal is deposited within the third plurality of trenches 140 to form FM alignment marks 145. The FM metal deposited within the third plurality of trenches 140 includes any ferromagnetic metal, such as cobalt (Co) or nickel (Ni). FM fill deposition adds the ferromagnetic metal within the third plurality of trenches 140 using standard processes of trench fill in a dielectric field and CMP polish.

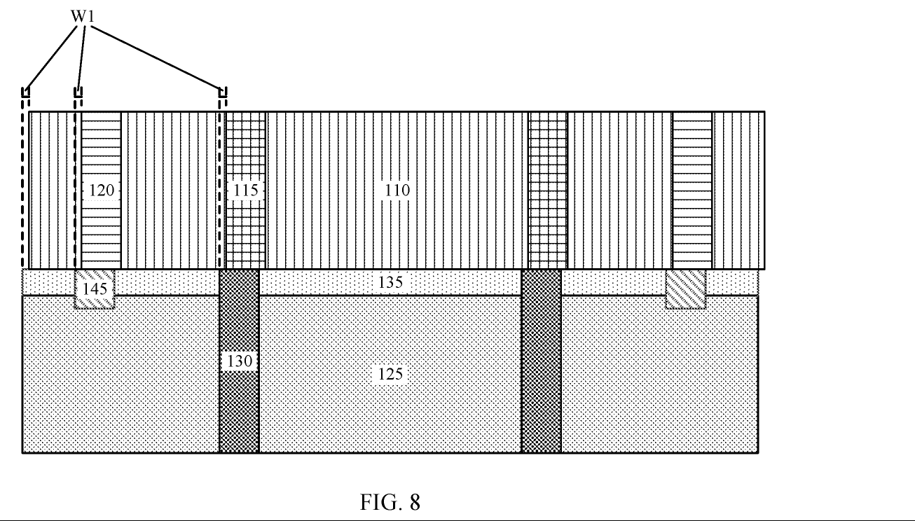

FIG. 8 illustrates a cross-sectional view of the reusable layer 110, 115, 120 and a product wafer after optical alignment, according to the embodiment of the present invention. After formation of the FM alignment marks 145, the reusable layer 110, 115, 120 delaminated in FIG. 4 is optically placed directly atop the etch/CMP stop layer 135, the product chip interconnects 130, and the FM alignment marks 145. During optical alignment, the flexible layer 110 is optically aligned with the etch/CMP stop layer 135, the flexible layer interconnects 115 are optically aligned with the product chip interconnects 130, and the FM fill region 120 is optically aligned with the FM alignment marks 145. Since only optical alignment is performed, a width W1 is present that represents the difference in total alignment of the flexible layer 110 with the etch/CMP stop layer 135, the flexible layer interconnects 115 with the product chip interconnects 130, and the FM fill region 120 with the FM alignment marks 145. Although depicted for frontside placement, the product wafer can be formed to allow for backside placement of the reuseable layer.

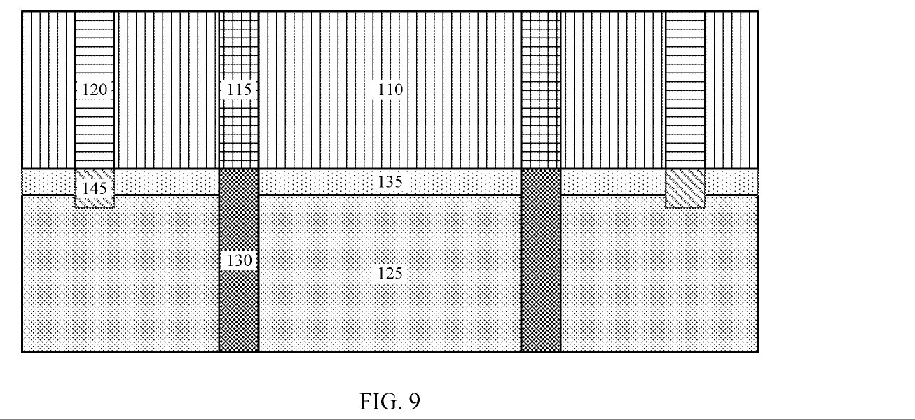

FIG. 9 illustrates a cross-sectional view of the reusable layer 110, 115, 120 and a product wafer after FM fine alignment, according to the embodiment of the present invention. FM fine alignment utilizes ferromagnetism to align the FM fill region 120 with FM alignment marks 145, the flexible layer interconnects 115 with the product chip interconnects 130, and the flexible layer 110 with the stop layer 135 more accurately than possible through optical alignment. FM fine alignment is achieved through the application of a localized magnetic field to align the polymer of the reuseable layer 110, 115, 120 with the product wafer. After performing FM fine alignment, width W1 is no longer present and the flexible layer 110 is directly atop the etch/CMP stop layer 135, the flexible layer interconnects 115 are directly atop the product chip interconnects 130, and the FM fill region 120 is directly atop the FM alignment marks 145. After performing FM fine alignment, pressure is applied to the frontside of the flexible layer 110 to ensure proper contact with the etch/CMP stop layer 135 of the product chip 125.

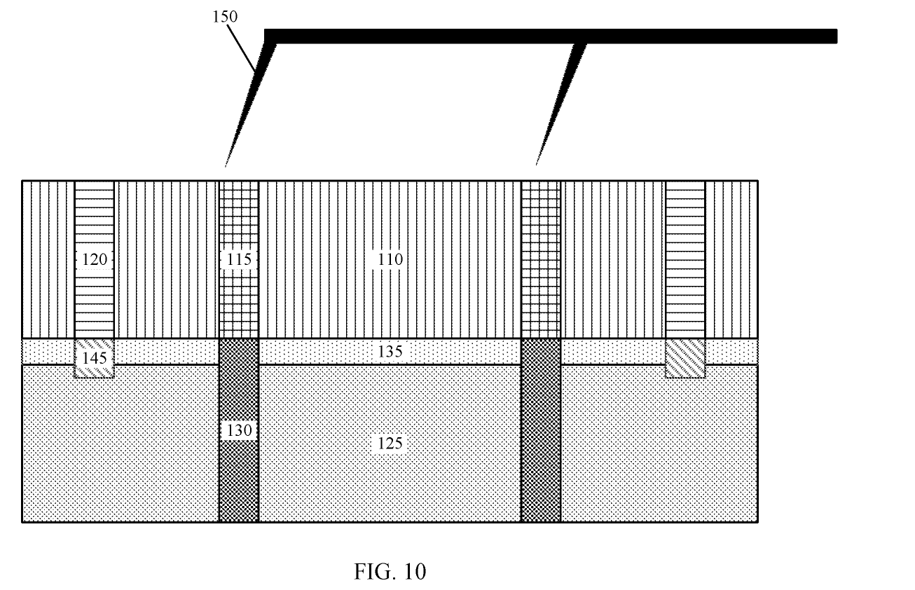

FIG. 10 illustrates a cross-sectional view of the reusable layer 110, 115, 120 and a product wafer with a probe testing configuration, according to the embodiment of the present invention. An electrical connection tester 150 is utilized to test the product chip 125. The electrical connection tester 150 is connected to the frontside surface of the flexible layer interconnects 115 and the product chip 125 is tested through industry standard methods for the particular chip. The arrangement of the various components enable electrical testing while maintaining precise alignment between the flexible layer 110 and the product chip 125.

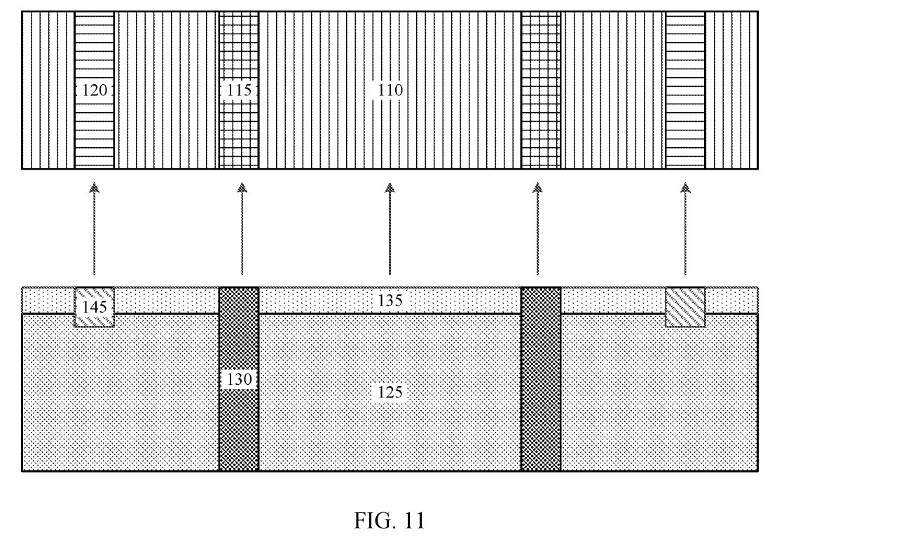

FIG. 11 illustrates a cross-sectional view of separation of the reusable layer110, 115, 120 from the product wafer, according to the embodiment of the present invention. Upon completion of the testing process, the electrical connection tester 150 is removed from placement on the frontside of the reusable layer 110, 115, 120 and the reusable layer 110, 115, 120 is separated from the product wafer. The reusable layer 110, 115, 120 is then ready and capable of testing with other product wafers.

It may be appreciated that FIGS. 1-11 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a flexible layer substrate;
a plurality of ferromagnetic fill regions extending through the flexible layer substrate;
a product chip under the flexible layer substrate; and
a plurality of ferromagnetic alignment marks extending through a portion of the product chip, wherein the plurality of ferromagnetic fill regions and the plurality of ferromagnetic alignment marks are aligned through ferromagnetism.

2. The semiconductor device of claim 1, wherein the plurality of ferromagnetic fill regions and the plurality of ferromagnetic alignment marks are configured to be aligned through a localized magnetic field.

3. The semiconductor device of claim 1, the flexible layer substrate includes a flexible polymer material.

4. The semiconductor device of claim 1, wherein the flexible layer substrate and the plurality of ferromagnetic fill regions are configured to be removed and reused.

5. The semiconductor device of claim 1, further comprising:
an electrical connection tester connected to a frontside of the flexible layer substrate.

6. The semiconductor device of claim 1, wherein the plurality of ferromagnetic fill regions and the plurality of ferromagnetic alignment marks are comprised of cobalt (Co).

7. The semiconductor device of claim 1, wherein the plurality of ferromagnetic fill regions and the plurality of ferromagnetic alignment marks are comprised of nickel (Ni).

8. A semiconductor device comprising:
a flexible layer substrate;
a plurality of ferromagnetic fill regions extending through the flexible layer substrate;
a product chip under the flexible layer substrate;
a stop layer connected to a frontside surface of the product chip; and
a plurality of ferromagnetic alignment marks extending through the stop layer and a portion of the product chip, wherein the plurality of ferromagnetic fill regions and the plurality of ferromagnetic alignment marks are aligned through ferromagnetism.

9. The semiconductor device of claim 8, wherein the plurality of ferromagnetic fill regions and the plurality of ferromagnetic alignment marks are configured to be aligned through a localized magnetic field.

10. The semiconductor device of claim 8, the flexible layer substrate includes a flexible polymer material.

11. The semiconductor device of claim 8, wherein the flexible layer substrate and the plurality of ferromagnetic fill regions are configured to be removed and reused.

12. The semiconductor device of claim 8, further comprising:
an electrical connection tester connected to a frontside of the flexible layer substrate.

13. The semiconductor device of claim 8, wherein the plurality of ferromagnetic fill regions and the plurality of ferromagnetic alignment marks are comprised of cobalt (Co).

14. The semiconductor device of claim 8, wherein the plurality of ferromagnetic fill regions and the plurality of ferromagnetic alignment marks are comprised of nickel (Ni).

15. A semiconductor device comprising:
a flexible layer substrate;
a plurality of flexible layer interconnects extending through the flexible layer substrate;
a plurality of ferromagnetic fill regions extending through the flexible layer substrate;
a product chip under the flexible layer substrate;
a stop layer connected to a frontside surface of the product chip;
a plurality of product chip interconnects extending through the stop layer and the product chip; and
a plurality of ferromagnetic alignment marks extending through the stop layer and a portion of the product chip, wherein the plurality of ferromagnetic fill regions and the plurality of ferromagnetic alignment marks are aligned through ferromagnetism.

16. The semiconductor device of claim 15, wherein the plurality of ferromagnetic fill regions and the plurality of ferromagnetic alignment marks are configured to be aligned through a localized magnetic field.

17. The semiconductor device of claim 15, the flexible layer substrate includes a flexible polymer material.

18. The semiconductor device of claim 15, wherein the flexible layer substrate, the plurality of interconnects, and the plurality of ferromagnetic fill regions configured to be removed and reused.

19. The semiconductor device of claim 15, further comprising:
an electrical connection tester connected to a frontside of the plurality of flexible layer interconnects.

20. The semiconductor device of claim 15, wherein the plurality of ferromagnetic fill regions and the plurality of ferromagnetic alignment marks are comprised of nickel (Ni).
